(19) United States
(12) Patent Application Publication
(10) Pub. No.: US 2016/0211417 A1
(43) Pub. Date: Jul. 21, 2016

(54) SEMICONDUCTOR LIGHT-EMITTING ELEMENT, LIGHT EMITTING DEVICE, AND METHOD OF MANUFACTURING SEMICONDUCTOR LIGHT-EMITTING ELEMENT

(71) Applicant: KABUSHIKI KAISHA TOSHIBA, Tokyo (JP)

(72) Inventors: Hiroshi KATSUNO, Komatsu Ishikawa (JP); Masakazu SAWANO, Nonoichi Ishikawa (JP); Koji KAGA, Komatsu Ishikawa (JP); Go OIKE, Nomi Ishikawa (JP); Kazuyuki MIYABE, Kanazawa Ishikawa (JP)

(21) Appl. No.: 14/993,269

(22) Filed: Jan. 12, 2016

(30) Foreign Application Priority Data
Jan. 16, 2015 (JP) 2015-006648

(51) Int. Cl. H01L 33/40; H01L 33/00; H01L 33/60; H01L 33/24; H01L 33/38

(52) U.S. Cl. CPC H01L 33/405; H01L 33/24; H01L 33/38; H01L 33/60; H01L 33/0075; H01L 2933/0016

(57) ABSTRACT

A semiconductor light-emitting element includes a stacked body having a first semiconductor layer of a first conductivity type, a second semiconductor layer of a second conductivity type, and a light emitting layer between the first and second semiconductor layers. A first metal layer is on the second semiconductor layer. The first metal layer includes a first region extending outward from the stacked body and a second region adjacent to the first region. A distance between a lower surface and an upper surface of the first metal layer in the first region is shorter than a distance between the lower end and the upper surface of the first metal layer in the second region. The lower and upper surfaces of the first metal layer in the first region extend along an outer edge of the first metal layer.

### CROSS-REFERENCE TO RELATED APPLICATION

This application is based upon and claims the benefit of priority from Japanese Patent Application No. 2015-006648, filed Jan. 16, 2015, the entire contents of which are incorporated herein by reference.

### FIELD

Embodiments described herein relate generally to a semiconductor light-emitting element, a light emitting device, and a method of manufacturing the semiconductor light-emitting element.

### BACKGROUND

A semiconductor light-emitting element such as a light emitting diode (LED) includes a stacked body that includes a p-type semiconductor layer, a light emitting layer, and an n-type semiconductor layer. A metal layer is electrically connected to the n-type semiconductor layer or a p-type semiconductor layer through an ohmic electrode. Among these semiconductor light-emitting elements, there is a semiconductor light-emitting element in which the metal layer extends outward from the stacked body.

However, when light that is emitted from a light emitting layer reaches the metal layer that extends outward from the stacked body, in some cases, reflection or absorption of the light due to the metal layer occurs and light emitting efficiency of the semiconductor light-emitting element is reduced.

DESCRIPTION OF THE DRAWINGS

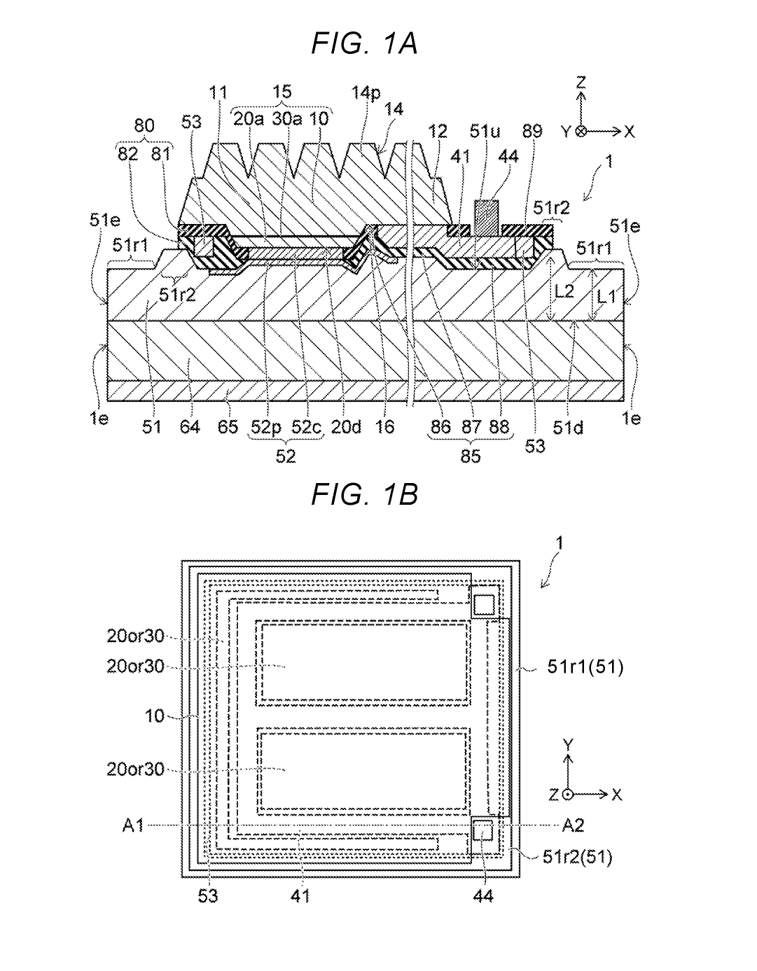

FIG. 1A is a schematic cross-sectional diagram illustrating main portions of a semiconductor light-emitting element according to a first embodiment.

FIG. 1B is a schematic top view illustrating the main portions of the semiconductor light-emitting element according to the first embodiment.

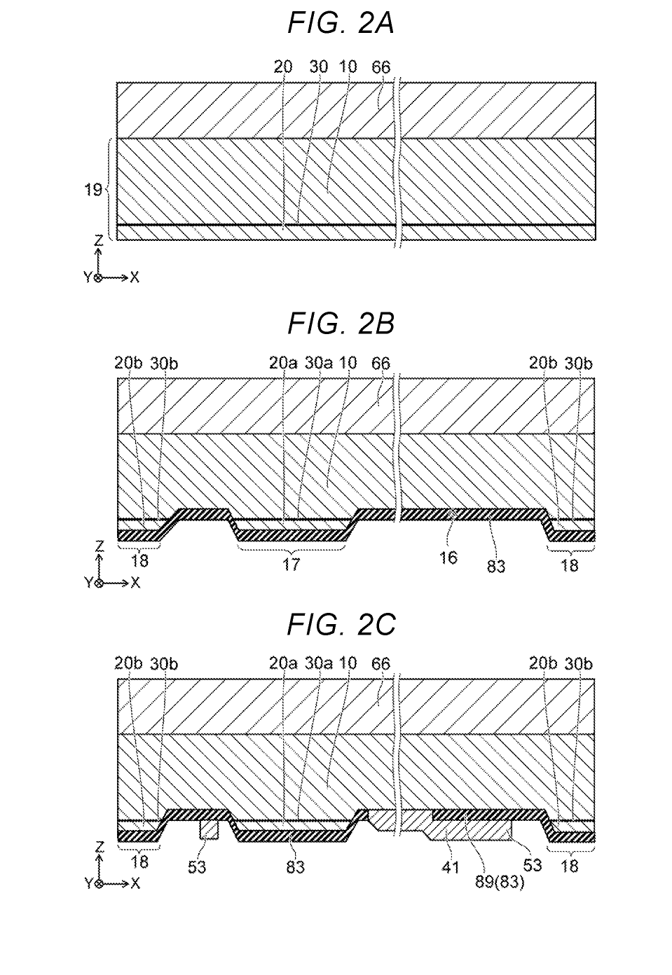

FIGS. 2A to 2C are schematic cross-sectional diagrams illustrating a process of manufacturing the main portions of the semiconductor light-emitting element according to the first embodiment.

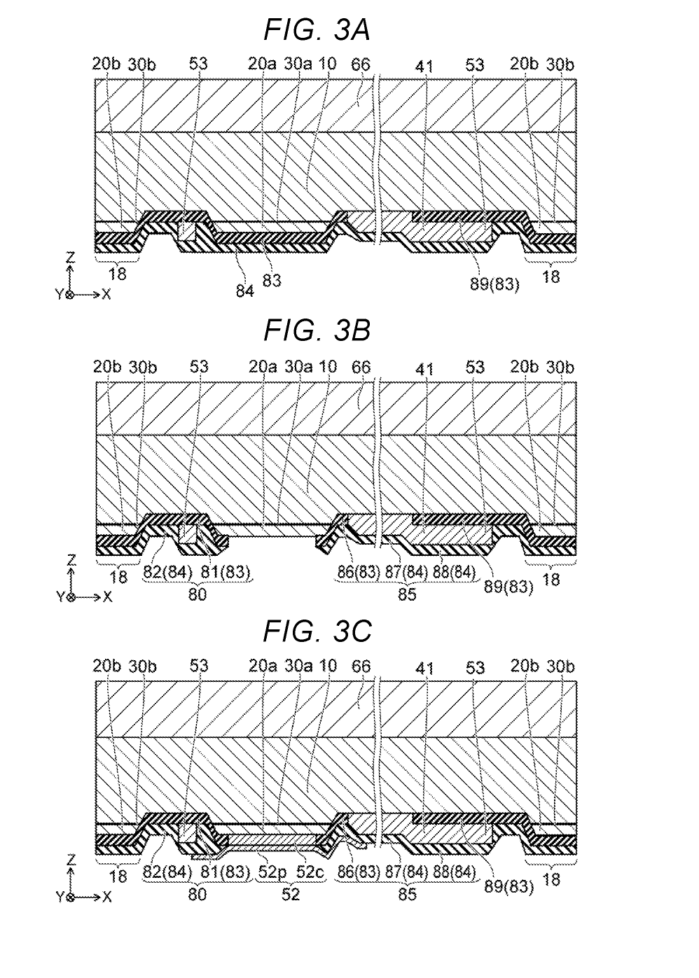

FIGS. 3A to 3C are schematic cross-sectional diagrams illustrating the process of manufacturing the main portions of the semiconductor light-emitting element according to the first embodiment.

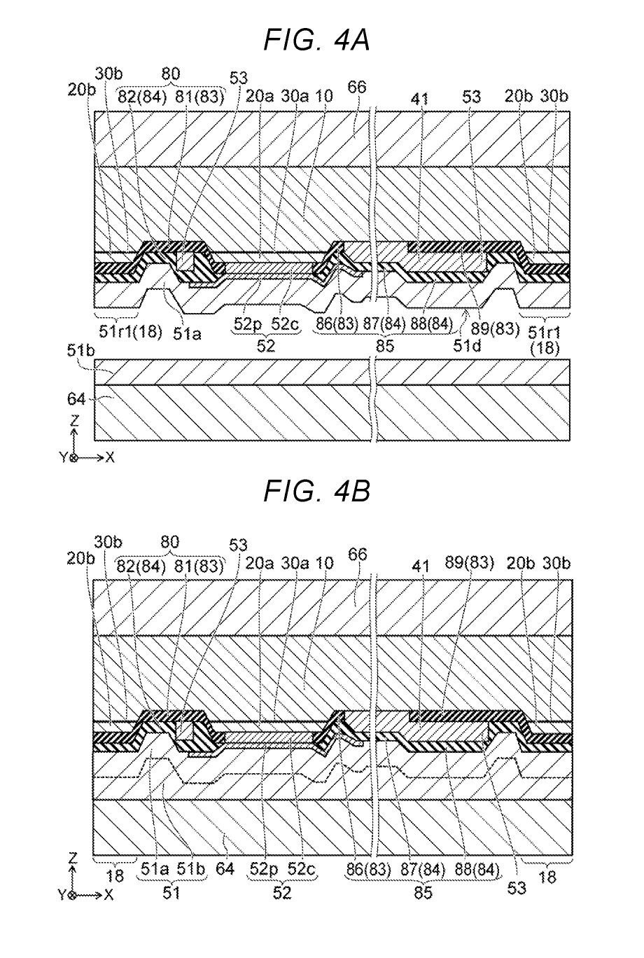

FIGS. 4A to 4B are schematic cross-sectional diagrams illustrating the process of manufacturing the main portions of the semiconductor light-emitting element according to the first embodiment.

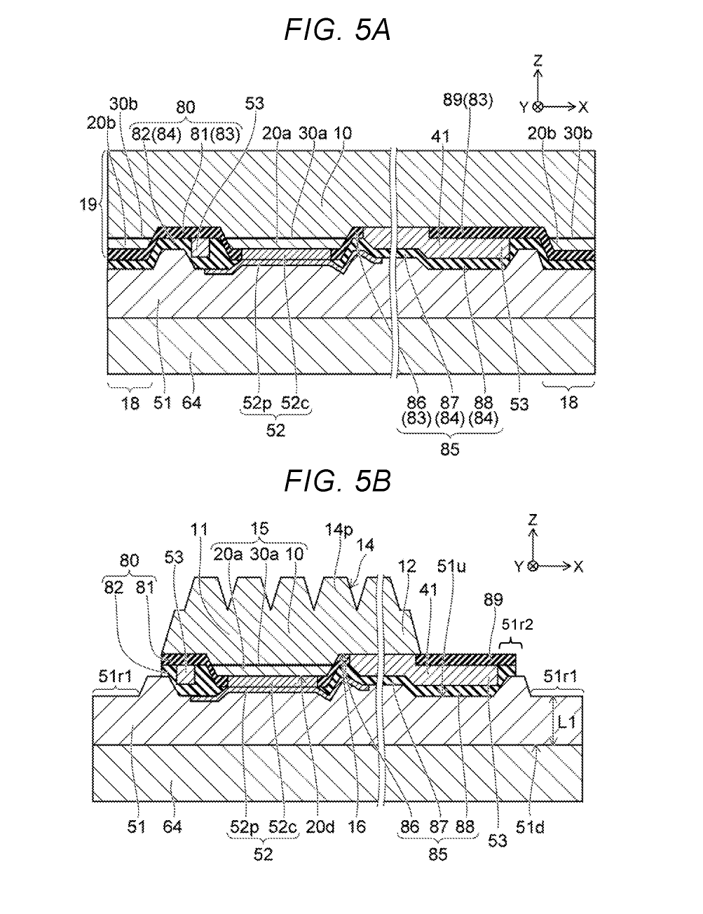

FIGS. 5A to 5B are schematic cross-sectional diagrams illustrating the process of manufacturing the main portions of the semiconductor light-emitting element according to the first embodiment.

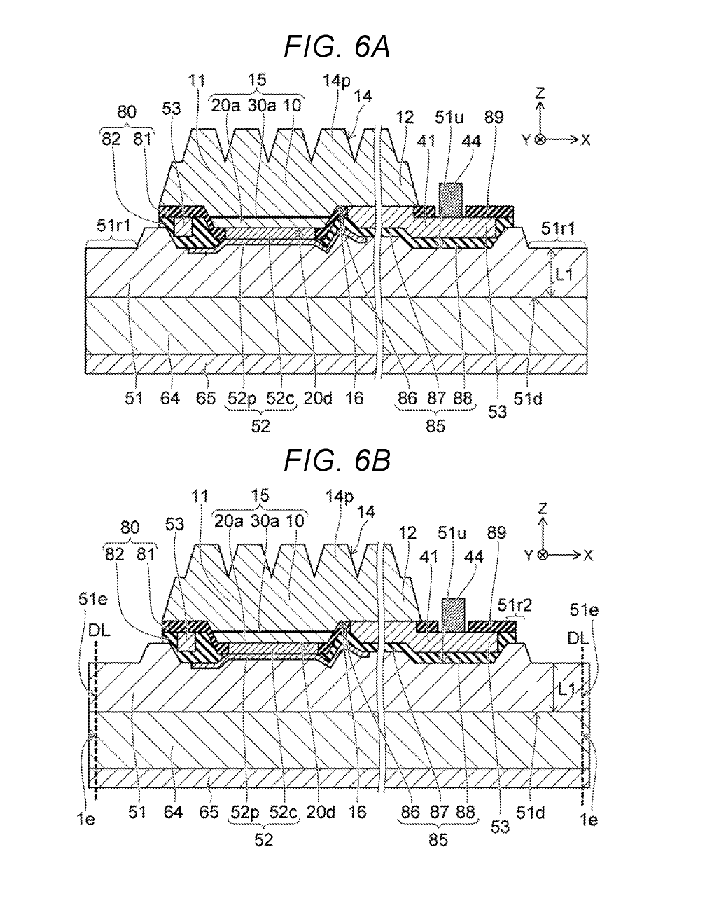

FIGS. 6A to 6B are schematic cross-sectional diagrams illustrating the process of manufacturing the main portions of the semiconductor light-emitting element according to the first embodiment.

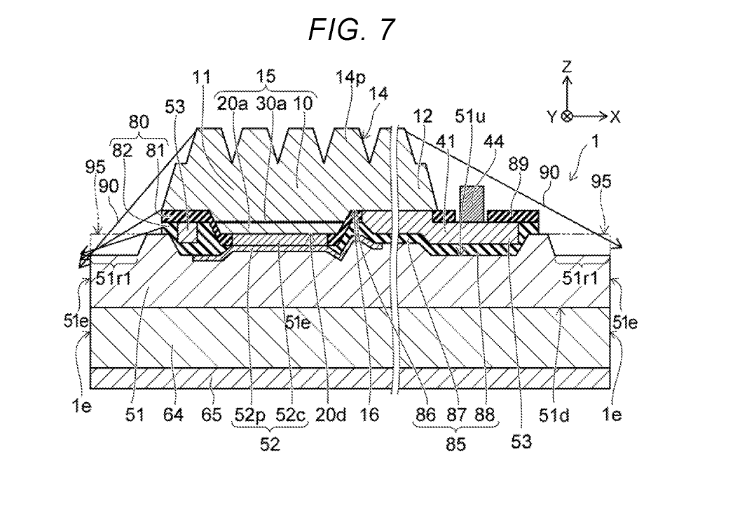

FIG. 7 is a schematic cross-sectional diagram illustrating an effect of the semiconductor light-emitting element according to the first embodiment.

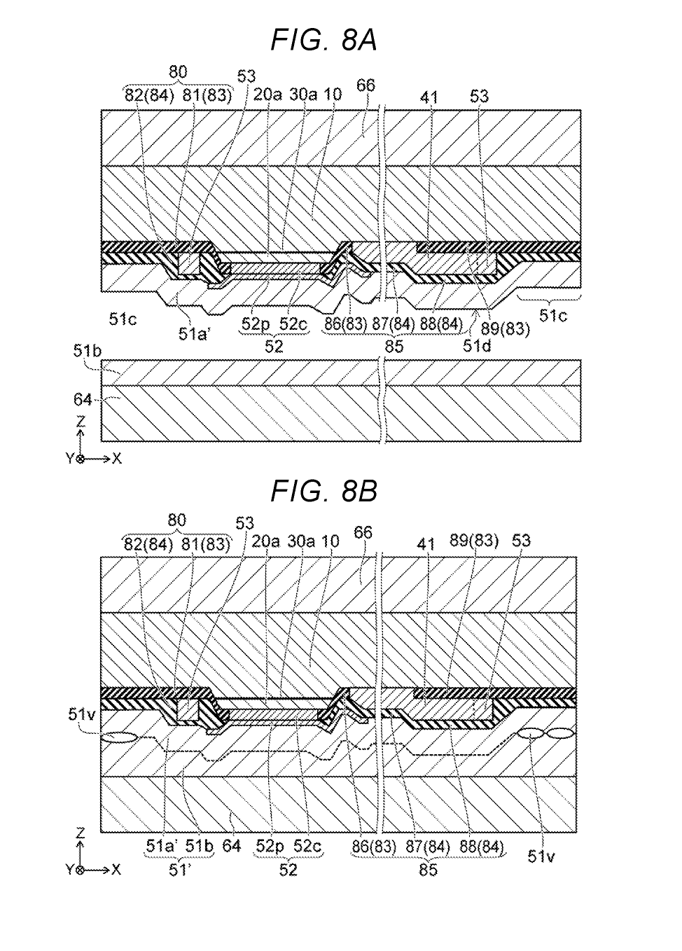

FIGS. 8A and 8B are schematic cross-sectional diagrams illustrating a process of manufacturing a semiconductor light-emitting element according to a reference example.

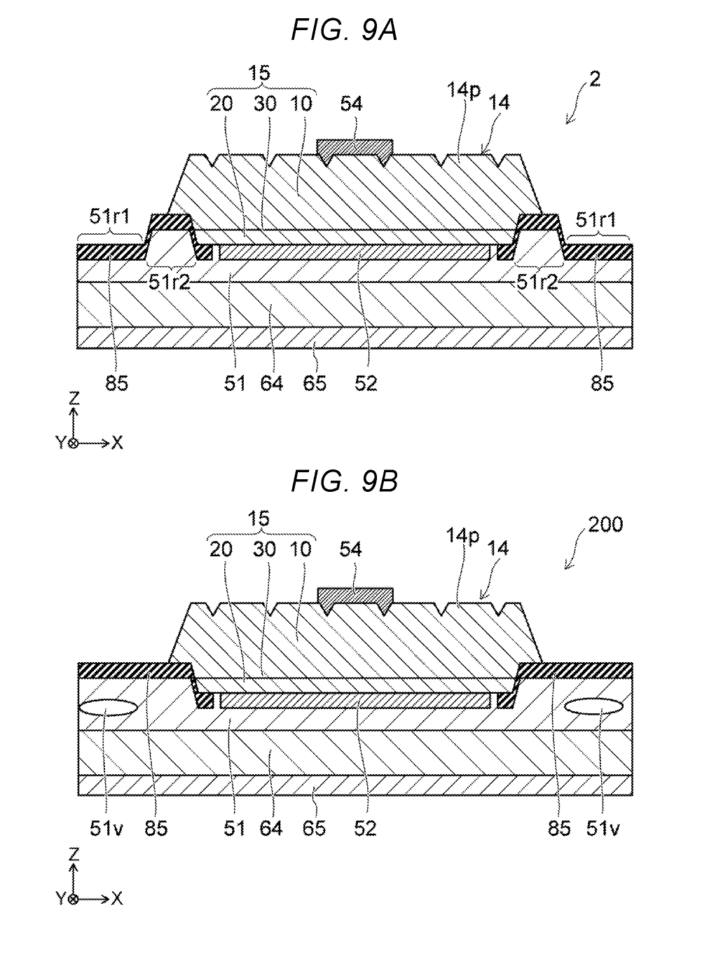

FIG. 9A is a schematic cross-sectional diagram illustrating main portions of a semiconductor light-emitting element according to a second embodiment, and FIG. 9B is a schematic cross-sectional diagram illustrating main portions of a semiconductor light-emitting element according to a reference example.

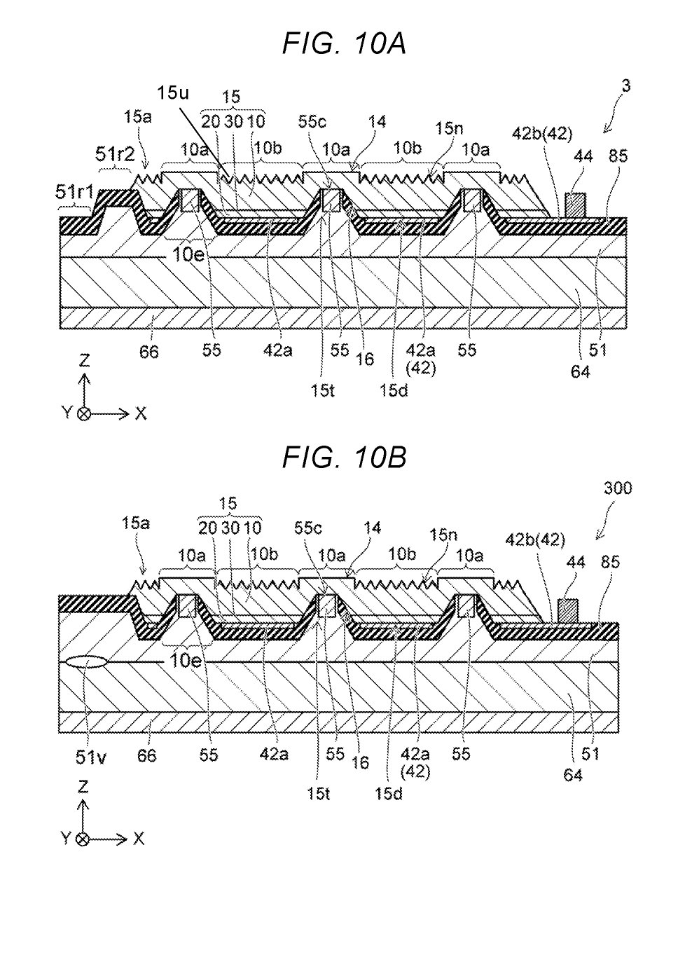

FIG. 10A is a schematic cross-sectional diagram illustrating main portions of a semiconductor light-emitting element according to a third embodiment, and FIG. 10B is a schematic cross-sectional diagram illustrating main portions of a semiconductor light-emitting element according to a reference example.

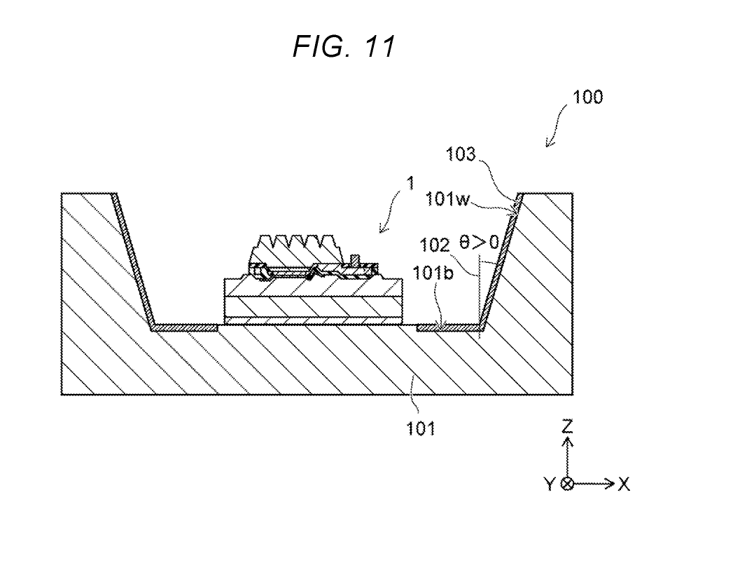

FIG. 11 is a schematic cross-sectional diagram illustrating main portions of a light-emitting device according to a fourth embodiment.

### DETAILED DESCRIPTION

Example mbodiments described herein provide a semiconductor light-emitting element, a light emitting device, and a method of manufacturing the semiconductor light-emitting element, all of which improves light emitting efficiency.

In general, according to one embodiment, a semiconductor light-emitting element includes a stacked body that includes a first semiconductor layer that is a first conductivity type, a second semiconductor layer that is a second conductivity type, and a light emitting layer between the first semiconductor layer and the second semiconductor layer, and a first metal layer on the second semiconductor layer, and electrically connected to the second semiconductor layer of the stacked body. The first metal layer includes a first region that extends outward from the stacked body, and a second region that is adjacent to the first region. A distance between a lower end of the first metal layer and an upper end of the first metal layer in the first region is shorter than a distance between the lower end of the first metal layer and the upper end of the first metal layer in the second region. The lower end of the first metal layer and the upper end of the first metal layer in the first region extends along an outer edge of the first metal layer.

Embodiments will be described below with reference to the drawings. In the following description, like members are given like reference numerals, and repetitious descriptions of the same number is suitably avoided. In the drawings, in some cases, XYZ coordinates are used. According to embodiments, a first conductivity type may be a p type, and a second conductivity type is an n type. The first conductivity type may be the n type and the second conductivity type may be the p type. In the following example, the first conductivity type is defined as the n type, and the second conductivity type is defined as the p type.

### First Embodiment

FIG. 1A is a schematic cross-sectional diagram illustrating main portions of a semiconductor light-emitting element according to a first embodiment. FIG. 1B is a schematic top-view diagram illustrating the main portions of the semiconductor light-emitting element according to the first embodiment.

FIG. 1A illustrates a cross section whose location is shown by line A1 to A2 on FIG. 1B. FIG. 1B is a top-view diagram that illustrates a portion of the semiconductor light-emitting element according to the embodiment are provided. Structures that are illustrated in FIGS. 1A and 1B are only examples, and the illustrated structures do not impose any limitation.

A semiconductor light-emitting element 1 according to the first embodiment includes a first semiconductor layer 10, a second semiconductor layer 20a, a light emitting layer 30a, a first metal layer 51, and a first conductive layer 41. The stacked body that includes the first semiconductor layer 10, the second semiconductor layer 20a, and the light emitting layer 30a is a semiconductor light-emitting portion 15.

A conductivity type of the first semiconductor layer 10 is, for example, an n type. A conductivity type of the second semiconductor layer 20a is, for example, a p type. The light emitting layer 30a is provided between the first semiconductor layer 10 and the second semiconductor layer 20a.

The first metal layer 51 is provided on the semiconductor light-emitting portion 15 on the semiconductor layer 20a side. In one embodiment, the first metal layer 51 is provided under the semiconductor light-emitting portion 15. The first metal layer 51 is electrically connected to the second semiconductor layer 20a of the semiconductor light-emitting portion 15.

The first metal layer 51 extends outward from the semiconductor light-emitting portion 15. In this disclosure, “outward” means being farther away from the center of the semiconductor light-emitting element 1 in a direction from the center of the semiconductor light-emitting element 1 to an outer edge 1e of the semiconductor light-emitting element 1. Conversely, being farther away from the outer edge 1e of the semiconductor light-emitting element 1 in the direction from the outer edge 1e of the semiconductor light-emitting element 1 to the center of the semiconductor light-emitting element 1 is defined as being “inward.”

The first metal layer 51 that extends outward from the semiconductor light-emitting portion 15 includes a first region 51r1 and a second region 51r2 adjacent to the first region 51r1. In this disclosure, when the first region 51r1 is “adjacent to” the second region 51r2, this means that the first region 51r1 is connected to the second region 51r2 in an X-axis direction and in a Y-axis direction. In other embodiments, the first region 51r1 may be separated from the second region 51r2. A distance L1 between a lower end 51d of the first metal layer 51 and an upper end 51u of the first metal layer 51 in the first region 51r1 is shorter than a distance L2 between the lower end 51d of the first metal layer 51 and the upper end 51u of the first metal layer 51 in the second region 51r2. Thus, the second region 51r2 is thicker than the first region 51r1 in this embodiment. The lower end 51d of the first metal layer 51 and the upper end 51u of the first metal layer 51 in the first region 51r1 is connected to an outer edge 51e of the first metal layer 51. That is, the first metal layer 51 does not extend outward from the first region 51r1. In other words, the first region 51r1 is at the outer edge 51e of the first metal layer 51. The outer edge 51e of the first metal layer 51 is at an outer edge 1e of the semiconductor light-emitting element 1. A width of the first region 51r1 along a cross-section parallel to an X-Z plane or a Y-Z plane may be between 0.5 μm and 100 μm. The smaller the width of the first region 51r1, the greater the number of chips obtained per wafer and the more a chip cost decreases. The greater the width of the first region 51r1, the more a margin of a dicing process to be described below is increased and the better a yield. Furthermore, the distance L1 maybe between 0.5 μm and 200 μm, and the distance L2 may be between 0.5 μm and 200 μm. If the first region 51r1 is projected onto an X-Y plane, the first region 51r1 surrounds the semiconductor light-emitting portion 15, the first conductive layer 41, a metal layer 52, a metal layer 53,a pad electrode 44, interlayer insulating layers 80 and 85, and an insulating layer 89.

The first semiconductor layer 10 has a first surface 14, a second surface second surface 16 that is opposite to the first surface 14.

The light emitting layer 30a is selectively provided on the second surface 16 of the first semiconductor layer 10. A portion of the first conductive layer 41 is provided between the second surface 16 of the first semiconductor layer 10 and the first metal layer 51, in an area where the light emitting layer 30a is not located. The first conductive layer 41 is electrically connected to the second surface 16 of the first semiconductor layer 10. In an embodiment wherein the first semiconductor layer 10 has an n type conductivity, the first conductive layer 41 is a portion of an electrode connected to the first semiconductor layer 10 of the n-type conductivity. The first conductive layer 41 extends outward from the semiconductor light-emitting portion 15. The first region 51r1 is provided outward from the first conductive layer 41. A reflectance of the first conductive layer 41 to light that is radiated from the light emitting layer 30a may be higher than a reflectance of the first metal layer 51.

The semiconductor light-emitting element 1 may further include a sealing portion (not illustrated) that covers the semiconductor light-emitting portion 15. For the sealing portion, resin may be used. The sealing portion may include a wavelength conversion body that absorbs a portion of an emission light that is radiated from the semiconductor light-emitting element 1 and emits light having a different wavelength (for example a peak wavelength) from a wavelength (for example a peak wavelength) of the emission light. For the wavelength conversion body, a fluorescent body is used.

The semiconductor light-emitting element 1 is further described in detail.

In the semiconductor light-emitting element 1, a supporting substrate 64 is provided on a back surface electrode 65. The supporting substrate 64, when projected on the X-Y plane, overlaps the first semiconductor layer 10. An area of the supporting substrate 64 is equal to or greater than an area of the first semiconductor layer 10. A semiconductor substrate that is made of Si may be used as the supporting substrate 64. As the supporting substrate 64, a metal substrate that is made of Cu or CuW (copper tungsten) may be used. As the supporting substrate 64, a deposition layer (such as a thick-film deposition layer) may be used. Thus, the supporting substrate 64 may be formed by deposition.

The back surface electrode 65 is provided on a side of the supporting substrate 64 that is opposite to a side of the supporting substrate 64 facing the semiconductor light-emitting portion 15. For the back surface electrode 65, a stack film that includes a Ti film, a Pt film, and a Au film maybe used. In one embodiment, the Pt film is arranged between the Au film and the supporting substrate 64, and the Ti film is arranged between the Pt film and the supporting substrate 64.

The first metal layer 51 described above maybe provided on the supporting substrate 64. On the side of the first metal layer 51 toward the semiconductor light-emitting portion 15, a metal that has high adhesion or a metal that has high resistance to an etchant or other processing conditions can be used, even if the metal has a low reflectance. Use of a metal that has high adhesion may provide useful adhesion between the metal layer 52 and the interlayer insulating layers 80 and 85.

The first metal layer 51 may include at least one of Ti, Pt, Ni, and solder material. The solder material that is contained in the first metal layer 51 may include at least one of Ni—Sn system solder, Au—Sn system solder, Bi—Sn system solder, Sn—Cu system solder, Sn—In system solder, Sn—Ag system solder, Sn—Pb system solder, Pb—Sn—Sb system solder, Sn—Sb system solder, Sn—Pb—Bi system solder, Sn—Pb—Cu system solder, Sn—Pb—Ag system solder, and Pb—Ag system solder. In one embodiment, at least one of Ti, Pt, and Ni is provided between the solder material and the supporting substrate 64, between the solder material and the interlayer insulating layers 80 and 85, and between the solder member and the metal layer 52.

Furthermore, as material of the first metal layer 51, Ti (titanium) or TiW (titanium tungsten) may be used. Furthermore, as the first metal layer 51, the stack film that includes the Ti film, the Pt film, and the Au film may be used. In one embodiment, a Pt (platinum) film is arranged between a Au (Gold) film and the semiconductor light-emitting portion 15, and a Ti (titanium) film is arranged between the Pt film and the semiconductor light-emitting portion 15.

According to one embodiment, a direction from the first metal layer 51 to the semiconductor light-emitting portion 15 is defined as a first direction (hereinafter referred to as, for example, a Z-axis direction). A direction that is perpendicular to the Z-axis direction is defined as the X-axis direction. A direction that is perpendicular to the Z-axis direction and the X-axis direction is defined as the Y-axis direction. Thus, in the embodiment of FIG. 1A, the semiconductor light-emitting portion 15 is separated from the first metal layer 51 in the Z-axis direction.

The first metal layer 51 may have a rectangular projection onto the X-Y plane. The first semiconductor layer 10 of the semiconductor light-emitting portion 15 may have a rectangular projection onto the X-Y plane. However, according to the embodiment, the shape of the first metal layer 51 and the semiconductor light-emitting portion 15 projections is arbitrary.

A joining layer may be provided between the supporting substrate 64 and the first metal layer 51. The supporting substrate 64 is usually conductive. The back surface electrode 65 may be connected to the first metal layer 51 through the supporting substrate 64.

The first metal layer 51 is arranged between the supporting substrate 64 and the semiconductor light-emitting portion 15. The metal layer 52 is provided on the first metal layer 51. The supporting substrate 64 and the metal layer 52 are electrically connected to each other through the first metal layer 51. The metal layer 52 may be provided on a planar center portion of the first metal layer 51. The metal layer 52 includes a contact metal portion 52c and a surrounding metal portion 52p that is provided adjacent to the contact metal portion 52c. In an embodiment wherein the second semiconductor layer 20a has p type conductivity, the metal layer 52 is an electrode connected to the second semiconductor layer 20a of p-type conductivity. The metal layer 52 is reflective. At least one of Al and Ag may be included in the metal layer 52.

The contact metal portion 52c may come into ohmic contact with the second semiconductor layer 20a. The contact metal portion 52c may have high reflection to the emission light. Increased reflectance of the contact metal portion 52c may improve light extraction efficiency. The light extraction efficiency means a ratio of a total luminous flux of light that maybe extracted outward from the semiconductor light-emitting element 1 to the total luminous fluxes of light that occur in the light emitting layer 30. In one embodiment, the contact metal portion 52c contains Ag.

The surrounding metal portion 52p covers at least a portion of the contact metal portion 52c and is electrically connected to the contact metal portion 52c. The surrounding metal portion 52p may have high reflectance to the emission light. Increased reflectance of the surrounding metal portion 52p may improve light extraction efficiency. In one embodiment the surrounding metal portion 52p contains Ag.

The semiconductor light-emitting portion 15 may be provided on the metal layer 52. The semiconductor light-emitting portion 15 includes a portion that is arranged on at least the contact metal portion 52c. The contact metal portion 52c thus comes into contact with the semiconductor light-emitting portion 15.

The first semiconductor layer 10 includes a first semiconductor portion 11 and a second semiconductor portion 12. The second semiconductor portion 12 is arranged with the first semiconductor portion 11 in a direction that is parallel with the X-Y plane. The second semiconductor layer 20a is provided between the first semiconductor portion 11 and the metal layer 52 (the contact metal portion 52c). The light emitting layer 30a is provided between the first semiconductor portion 11 and the second semiconductor layer 20a.

The second semiconductor layer 20a is provided between the first semiconductor layer 10 and the contact metal portion 52c. The light emitting layer 30a is provided between the first semiconductor layer 10 and the second semiconductor layer 20a.

The first semiconductor layer 10, the second semiconductor layer 20a, and the light emitting layer 30a each comprise a nitride semiconductor. The first semiconductor layer 10, the second semiconductor layer 20a, and the light emitting layer 30a may each include AlₓGa_{1-x-y}In_{y}N (x≧0, y≧0, x+y≦1).

The first semiconductor layer 10 may include a Si-doped n-type GaN contact layer and a Si-doped n-type AlGaN clad layer. The Si-doped n-type AlGaN clad layer may be arranged between the Si-doped n-type GaN contact layer and the light emitting layer 30a. The first semiconductor layer 10 may further include a GaN buffer layer. The Si-doped n-type GaN contact layer may be arranged between the GaN buffer layer and the Si-doped n-type AlGaN clad layer. In this case, an opening portion is provided in the Si-doped n-type AlGaN clad layer, and the first conductive layer 41 is connected to the Si-doped n-type GaN contact layer through the opening portion.

The light emitting layer 30a, for example, has a multiple quantum well layer (MQW) structure. In the MQW structure, multiple barrier layers and multiple well layers are alternately stacked. AlGaInN or GaInN may be used for any or all the well layers.

In the present disclosure, “deposited on,” “formed on,” and “provided on” includes states where the relevant layers are a directly contacting each other and states where one or more layers are interposed between the different layers.

A Si-doped n-type AlGaN, such as a Si-doped n-type Al_{0.11}Ga_{0.89}N, may be used for any or all the barrier layers. A thickness of any or all the barrier layers is, for example, 2 nm to 30 nm. Among the barrier layers, the barrier layer closest to the second semiconductor layer 20a, which may be a p side barrier layer, maybe different from the other barrier layers, and may be thicker or thinner than the other barrier layers.

A wavelength (for example a peak wavelength) of the light that is radiated from the light emitting layer 30a may be 210 nm to 700 nm. The peak wavelength of the emission light may be, for example, 370 nm to 480 nm.

The second semiconductor layer 20a may include any or all of a non-doped AlGaN spacer layer, a Mg-doped p-type AlGaN clad layer, a Mg-doped p-type GaN contact layer, and a high-concentration Mg-doped p-type GaN contact layer. The Mg-doped p-type GaN contact layer may be arranged between the high-concentration Mg-doped p-type GaN contact layer and the light emitting layer 30a. The Mg-doped p-type AlGaN clad layer may be arranged between the Mg-doped p-type GaN contact layer and the light emitting layer 30a. The non-doped AlGaN spacer layer may be arranged between the Mg-doped p-type AlGaN clad layer and the light emitting layer 30a. For example, the second semiconductor layer 20a may include a non-doped Al_{0.11}Ga_{0.89}N spacer layer, a Mg-doped p-type Al_{0.28}Ga_{0.72}N clad layer, the Mg-doped p-type GaN contact layer, and the high-concentration Mg-doped p-type GaN contact layer.

Moreover, in the semiconductor layer described above, a composition, a composition ratio, a type of impurity, an impurity concentration, and a thickness may be varied.

The first conductive layer 41 as described above is disposed between the first metal layer 51 and the second semiconductor portion 12. The first conductive layer 41 is electrically connected to the pad electrode 44. As described above, the reflectance of the first conductive layer 41 may be high. For example, the first conductive layer 41 may contain at least one of Al and Ag. In other embodiments, a different conductive layer may be provided between the first conductive layer 41 and the second semiconductor portion 12. If the first conductive layer 41 is highly reflective, light shielding films, such as an electrode or other light shielding films, on an upper surface of the semiconductor light-emitting portion 15 may be avoided. In this way, the semiconductor light-emitting element 1 can achieve high light extraction efficiency. Thus, in one embodiment, aluminum (Al) may be used for the first conductive layer 41. An aluminum conductive layer has both ohmic accessibility to the first semiconductor layer 10 and high reflectance to light.

As shown in FIG. 1B, the pad electrode 44 is provided on a surface at the upper end 51u of the first metal layer 51 on the side facing the semiconductor light-emitting portion 15. The pad electrode 44, when projected onto the X-Y plane, does not overlap the semiconductor light-emitting portion 15. The pad electrode 44 may be a stack of a Ti film, with a thickness of for example 10 nm, a Pt film, with a thickness of, for example, 50 nm, and an Au film, with a thickness of, for example, 1000 nm, in this order.

In the semiconductor light-emitting element 1, a metal layer 53 having reflectance to light may be provided. For the metal layer 53, at least one of aluminum (Al) and silver (Ag) may be used. When the metal layer 53 is projected onto the X-Y plane, the metal layer 53 overlaps the surrounding metal portion 52p. When the metal layer 53 is projected onto the X-Y plane, the metal layer 53 overlaps a boundary portion of the semiconductor light-emitting portion 15 (not visible in FIGS. 1A or 1B) . When the semiconductor light-emitting portion 15 is projected onto the X-Y plane, a center portion of the semiconductor light-emitting portion 15 overlaps the metal layer 52, which may be reflective, and the boundary portion of the semiconductor light-emitting portion 15 overlaps the metal layer 53, which may also be reflective. The metal layer 53 may be electrically connected to the first conductive layer 41. The metal layer 53 and the first conductive layer 41 may have a stack structure.

In the semiconductor light-emitting element 1, the light that is radiated from the semiconductor light-emitting portion 15 is reflected from the metal layers 52 and 53 and the first conductive layer 41, and may travel upward. Accordingly, no light is transmitted into subjacent layers such as the supporting substrate 64, and the light extraction efficiency of the semiconductor light-emitting element 1 is increased.

The interlayer insulating layer 80 includes a first insulating portion 81 and a second insulating portion 82. The first insulating portion 81 is provided between the metal layer 53 and the semiconductor light-emitting portion 15. The second insulating portion 82 is provided between the metal layer 53 and the first metal layer 51. In some embodiments, the first insulating portion 81 and the second insulating portion 82 may be unitary, without any interface between the two portions.

For the interlayer insulating layer 80, a dielectric material or the like may be used. Specifically, for the interlayer insulating layer 80, silicon oxide, silicon nitride, or silicon oxynitrde may be used. Oxide of metal that is at least one of Al, Zr, Ti, Nb, Hf, and the like, nitride of metal that is at least one of Al, Zr, Ti, Nb, Hf, and the like, or oxynitride of metal that is at least one of Al, Zr, Ti, Nb, Hf, and the like may be used for the interlayer insulating layer 80.

An interlayer insulating layer 85 includes a first interlayer insulating portion 86, a second interlayer insulating portion 87, and a third interlayer insulating portion 88. The interlayer insulating layer 85 may be the same material as the interlayer insulating layer 80. At least a portion of the interlayer insulating layer 85 may be formed during a process that forms at least a portion of the interlayer insulating layer 80. Thus, portions of the interlayer insulating layer 85 and the interlayer insulating layer 80 may be formed at the same time in one process.

The first interlayer insulating portion 86 is disposed between the semiconductor light-emitting portion 15 and the second interlayer insulating portion 87. The second interlayer insulating portion 87 is disposed between the first conductive layer 41 and the first metal layer 51. The third interlayer insulating portion 88 is disposed between the pad electrode 44 and the first metal layer 51. The pad electrode 44 and the first conductive layer 41 are electrically insulated by the interlayer insulating layer 85 from the first metal layer 51.

The first surface 14 of the semiconductor light-emitting portion 15 is usually rough. The roughness is formed by a plurality of convex portions 14p. In some embodiments, it may be useful to have, among the plurality of convex portions 14p, a distance between two adjacent convex portions 14p equal to or greater than an emission wavelength of the emission light that is emitted from the semiconductor light-emitting portion 15. The emission wavelength may be a peak wavelength emitted by the semiconductor light-emitting portion 15. Such dimensions of the convex portion 14p may improve the light extraction efficiency of the semiconductor light-emitting element 1.

When the distance between the convex portions 14p is shorter than the emission wavelength, the emission light incident on the first semiconductor layer 10 is at least partially scattered or diffracted at surfaces between concave and convex portions resulting in reduced light extraction efficiency. The roughness of the first semiconductor layer 10 has the effect of increasing reflectance of the first surface 14, resulting in lower light extraction efficiency from the light emitting structures below.

When projected onto the X-Y plane, the convex portions 14p may have a hexagonal shape. The roughness of the first surface 14 may be formed by performing anisotropic etching on the first semiconductor layer 10 using a KOH solution. Accordingly, the emission light that is radiated from the light emitting layer 30a undergoes Lambertian reflectance at the first surface 14.

The roughness of the first surface 14 may be formed by dry etching using a mask, thus allowing incorporation of a desired design, improved reproducibility, and improved light extraction efficiency.

The semiconductor light-emitting element 1 may further include an insulating layer (not illustrated) that covers a side of the first semiconductor layer 10, a side of the light emitting layer 30a, and a side of the second semiconductor layer 20a. The insulating layer may include the same material as the first insulating portion 81. For example, the insulating layer may include SiO₂. The insulating layer functions as a protective film for the semiconductor light-emitting portion 15. Accordingly, degradation or exposure of the semiconductor light-emitting element 1 is suppressed.

A voltage is applied between the back surface electrode 65 and the pad electrode 44, and thus the voltage is applied to the light emitting layer 30a through the first metal layer 51, the metal layer 52, and the second semiconductor layer 20a, or through the first conductive layer 41 and the first semiconductor layer 10. Accordingly, light is radiated from the light emitting layer 30a.

The light that is radiated is emitted mainly toward the first semiconductor layer 10, outward from the element. A portion of the light that is radiated from the light emitting layer 30a travels toward the first semiconductor layer 10, and is emitted from the element. A different portion of the light that is radiated from the light emitting layer 30a is reflected, with high efficiency, from the reflective metal layer 52, travels toward the first semiconductor layer 10, and is emitted from the element.

A process of manufacturing the semiconductor light-emitting element 1 is described below.

FIGS. 2A to 6B are schematic cross-sectional diagrams illustrating a process of manufacturing the main portions of the semiconductor light-emitting element 1 according to the first embodiment. FIGS. 2A to 6B correspond to the cross section whose location is indicated by line A1 to A2 on FIG. 1B. In FIGS. 2A to 6B, the semiconductor light-emitting element 1 is represented in a pre-dicing configuration before separation into individual elements.

For example, as illustrated in FIG. 2A, the first semiconductor layer 10, a light emitting layer 30, and an initial semiconductor layer 20 are grown in this order by an epitaxy growth process on a growth substrate 66, which may include aluminum and/or silicon, and a stacked body 19 that includes the first semiconductor layer 10, the light emitting layer 30, and the semiconductor layer 20 is formed on the growth substrate 66.

Next, as illustrated in FIG. 2B, a portion of the initial semiconductor layer 20 and a portion of the light emitting layer 30 are removed by etching. A depth to which the etching is performed may be 0.1 um to 100 um, for example 0.4 um to 2 um. A lower limit to the depth to which the etching is performed is determined by a depth to which the first semiconductor layer 10 is exposed. Greater etch depth may provide better wave guide properties within the stacked body 19 and may improve light extraction efficiency. Smaller etch depth results in a thicker first semiconductor layer 10, reducing sheet resistance and operating voltage of the first semiconductor layer 10.

Alight emitting region 17 and a mesa region 18 are formed in the stacked body 19. The light emitting region 17 includes the first semiconductor layer 10, the light emitting layer 30a that is selectively provided on the second surface 16 of the first semiconductor layer 10, and the second semiconductor layer 20a that, together with the first semiconductor layer 10, sandwiches the light emitting layer 30a. The mesa region includes the first semiconductor layer 10, the light emitting layer 30b that is selectively provided on the second surface 16 of the first semiconductor layer 10, and a peripheral semiconductor layer 20b that, together with the first semiconductor layer 10, sandwiches a peripheral light emitting layer 30b. The mesa region 18 is positioned in a dicing line that is described below.

Next, an insulating layer 83 that covers the second surface 16 of the first semiconductor layer 10, the light emitting region 17, and the mesa region 18 is formed.

Next, as illustrated in FIG. 2C, portions of the insulating layer 83 that is formed on the second surface 16 of the first semiconductor layer 10 are selectively removed. Subsequently, the first conductive layer 41 that is electrically connected to the second surface 16 of the first semiconductor layer 10, and covers a portion of the insulating layer 83 is formed. A metal layer that comes into ohmic contact with the second surface 16 of the first semiconductor layer 10 may be separately formed independently of the first conductive layer 41. The insulating layer 83 between the first conductive layer 41 and the first semiconductor layer 10 is a precursor to the insulating layer 89 described above. Thus, the material of the insulating layer 89 is the same as the material of the insulating layer 83. Furthermore, the metal layer 53 that selectively covers the insulating layer 83 is formed. The metal layer 53 and the first conductive layer 41 maybe formed at the same time. The metal layer 53 maybe formed in the same process as the first conductive layer 41, and in such a case, the metal layer 53 and the first conductive layer 41 have the same stack structure and the same materials.

Next, as illustrated in FIG. 3A, an insulating layer 84 that covers the insulating layers 83 and 89 resulting from removal of portions of the insulating layer 83, the first conductive layer 41, and the metal layer 53 is formed.

Next, as illustrated in FIG. 3B, the insulating layer 84 and the insulating layer 83 are etched in such a manner that the second semiconductor layer 20a is exposed from the insulating layer 83 and the insulating layer 84. In this process, the interlayer insulating layer 80 and the interlayer insulating layer 85 are formed. Thereafter, the contact metal portion 52c that is electrically connected to the second semiconductor layer 20a and the surrounding metal portion 52p adjacent to the contact metal portion 52c are formed (FIG. 3C). Accordingly, the metal layer 52 that is electrically connected to the second semiconductor layer 20a is formed.

Next, as illustrated in FIG. 4A, metal region 51a, that is electrically connected to the second semiconductor layer 20a and covers the metal layer 52 and the interlayer insulating layers 80 and 85, is formed. Because the metal region 51a is formed along surfaces of the interlayer insulating layers 80 and 85 and along a surface of the metal layer 52, a lower surface 51d of the metal region 51a is not even. For example, a pattern of the mesa region 18 in convex shape is transferred to the lower surface 51d of the metal region 51a. A portion of the metal region 51a, onto which the pattern of the mesa region is transferred, corresponds to the first region 51r1 described above.

Subsequently, the supporting substrate 64 on which a metal region 51b is formed is caused to face the metal region 51a. Accordingly, the metal region 51a faces the metal region 51b.

Next, as illustrated in FIG. 4B, the metal region 51a and the metal region 51b are joined to each other. For example, the metal region 51a and the metal region 51b are joined to form the first metal layer 51, into which the metal region 51a and the metal region 51b are integrally combined. At this point, a roughness of the lower surface 51d of the metal region 51a disappears. The first metal layer 51 includes the metal region 51a and the metal region 51b.

Next, as illustrated in FIG. 5A, the growth substrate 66 is removed from the first semiconductor layer 10.

Next, as illustrated in FIG. 5B, the mesa region 18 of the stacked body 19 and a portion of the first semiconductor layer 10 are removed by lithography and Reactive Ion Etching (RIE). Furthermore, the convex portions 14p are formed on the first surface 14 of the first semiconductor layer 10. Subsequently, a portion of the interlayer insulating layer 80, a portion of the third interlayer insulating portion 88, and a portion of the insulating layer 89 are removed by lithography and RIE. In addition, a protective film may be formed on the first surface 14 of the first semiconductor layer 10. Each end of a portion of the remaining interlayer insulating layer 80, a portion of the third interlayer insulating portion 88, and a portion of the insulating layer 89 may be on the second region 51r2 as illustrated in FIG. 5B, and may be on the first region 51r1.

Accordingly, a structure in which the first metal layer 51 extends outward from the stacked body 19 is obtained. At this point, the insulating layer 89 on the first conductive layer 41 is exposed from the first semiconductor layer 10. Furthermore, the first conductive layer 41 extends from the second surface 16 of the first semiconductor layer 10, outward from the first semiconductor layer 10.

Next, as illustrated in FIG. 6A, the insulating layer 89 is selectively etched using a buffer hydrofluoric acid solution. Subsequently, the pad electrode 44 is formed that is electrically connected to the first conductive layer 41 exposed from the insulating layer 89. Additionally, the back surface electrode 65 is joined to the supporting substrate 64.

Next, as illustrated in FIG. 6B, the first region 51r1 of the first metal layer 51 is cut in the Z direction from the first semiconductor layer 10 to the second semiconductor layer 20a. Subsequently, the supporting substrate 64 underneath the first region 51r1 and the back surface electrode 65 are cut in the direction from the first semiconductor layer 10 to the second semiconductor layer 20a. A position where the first metal layer 51, the supporting substrate 64, and the back surface electrode 65 are cut is shown as a dicing line DL in FIG. 6B. Accordingly, the semiconductor light-emitting element 1 is formed that results from performing the cutting.

FIG. 7 is a schematic cross-sectional diagram illustrating an effect of the semiconductor light-emitting element 1 according to the first embodiment.

If the mesa region 18 is not formed during manufacture of the semiconductor light-emitting element 1, the upper end 51u in the first region 51r1 of the first metal layer 51 is not recessed as compared with the first embodiment (shown by dashed lines and reference numeral 95 in FIG. 7). Accordingly, light 90 radiated from the light emitting layer 30 reaches a peripheral portion of the first metal layer 51 and is absorbed into the first metal layer 51. The light that is absorbed into the first metal layer 51, for example, is converted into heat.

In contrast, in the semiconductor light-emitting element 1, the upper end 51u in the first region 51r1 of the first metal layer 51 is recessed as compared with the reference example. For this reason, the light 90 that is radiated from the light emitting layer 30 may travel outward from the semiconductor light-emitting portion 15 without reaching the upper end 51u of the first region 51r1, and may travel outward from the outer edge 51e of the first metal layer 51.

The light may be reflected from a reflector or the like outside of the semiconductor light-emitting element 1, and for example, travels above the semiconductor light-emitting element 1 without being absorbed by any structures of the semiconductor light-emitting element 1. Alternatively, the light reaches a fluorescent body as well. Accordingly, light emitting efficiency of the semiconductor light-emitting element 1 is increased. In this disclosure, light emitting efficiency is defined as a ratio of total luminous flux of the light that is radiated by the semiconductor light-emitting element 1 outward from the semiconductor light-emitting element 1 to electric power that is applied to the semiconductor light-emitting element 1. Light emitting efficiency may be directional. Thus, the light emitting efficiency may be defined as a ratio that results from dividing the total luminous flux of the light that is radiated by the semiconductor light-emitting element 1 in a predetermined direction outward from the semiconductor light-emitting element 1, by the electric power that is applied to the semiconductor light-emitting element 1. When the light emitting region 17 is formed, a difference between the distance L1 and the distance L2 is substantially consistent with the depth to which the stacked body 19 is etched. The greater the difference between L1 and L2, the harder it is for light 90 radiated from the light emitting layer 30 to reach the peripheral portion of the first metal layer 51, resulting in better light emitting efficiency of the semiconductor light-emitting element 1.

FIGS. 8A and 8B are schematic cross-sectional diagrams illustrating a process of manufacturing a semiconductor light-emitting element according to the reference example, which results in L1 being the same as L2.

For example, as illustrated in FIG. 8A, in a case where the semiconductor light-emitting element is manufactured without the mesa region 18 in the stacked body 19, the pattern of the mesa region 18 is not transferred to a metal region 51a′. Accordingly, a deep-recessed concave portion 51c is formed in the metal region 51a′. In contrast, in FIG. 4A, the mesa region 18 in the stacked body 19 results in a first region 51r1 is not recessed. Furthermore, because the concave portion 51c is positioned in the dicing line, semiconductor light-emitting element formed according to the reference example has a peripheral portion that can intercept and absorb emitted light.

Additionally, in the reference example of FIGS. 8A and 8B, when the metal region 51a′ and the metal region 51b are joined to each other, because the metal region 51a′ and the metal region 51b are separated from each other at the position of the concave portion 51c, a void 51v may form (FIG. 8B). Any such void 51v would also be positioned in the dicing line.

In such a state, when the metal layer 51′ is cut along the dicing line, a void 51v may result in peeling of the metal regioin 51a′ from the metal region 51b with the void 51v as a starting point, which may further result in electric current leaks and short circuits within the semiconductor light-emitting element.

In contrast, according to the first embodiment, as illustrated in FIG. 4A, the pattern of the mesa region 18 in convex shape is transferred to the metal region 51a, as described above. The concave portion 51c and the void 51v of the reference example are not formed in the metal region 51a. Thus, peeling does not occur, and reliability and manufacturing yield of the semiconductor light-emitting element 1 according to the first embodiment are improved.

### Second Embodiment

FIG. 9A is a schematic cross-sectional diagram illustrating main portions of a semiconductor light-emitting element 2 according to a second embodiment. FIG. 9B is a schematic cross-sectional diagram illustrating main portions of a semiconductor light-emitting element 200 according to a reference example.

In a semiconductor light-emitting element 2 that is illustrated in FIG. 9A, a second metal layer 54 is formed on the first surface 14 of the first semiconductor layer 10. If the first semiconductor layer 10 has n type conductivity, the second metal layer 54 maybe an n type electrode. A metal layer 52 is provided as an electrode between the first metal layer 51 and the semiconductor light-emitting portion 15, and may be a p type electrode if the second semiconductor layer 20 has p type conductivity. The first metal layer 51 is electrically connected to the semiconductor layer 20 through the metal layer 52. In addition, a dielectric material layer 85 as a passivation film is provided on the first region 51r1 of the first metal layer 51 and on a second region 51r2 of the first metal layer 51.

FIG. 9B illustrates a semiconductor light-emitting element 200 as a reference example. In the semiconductor light-emitting element 200 that is illustrated in FIG. 9B, the first region 51r1 is not present. Therefore, in the semiconductor light-emitting element 200, light that is radiated from the light emitting layer 30 travels to the first metal layer 51 directly or through the dielectric material layer 85, or a void 51v is formed within the first metal layer 51 during the manufacturing process as described above.

In contrast, in the semiconductor light-emitting element 2 that is illustrated in FIG. 9A, the first region 51r1 is adjacent to the second region 51r2, so light that is radiated from the light emitting layer 30 does not reach the first metal layer 51, and no void 51v is formed during the manufacturing process. Therefore, the light emitting efficiency of the semiconductor light-emitting element 2 is improved, and reliability and manufacturing yield are increased, relative to the reference example of FIG. 9B.

### Third Embodiment

FIG. 10A is a schematic cross-sectional diagram illustrating main portions of a semiconductor light-emitting element 3 according to a third embodiment. FIG. 10B is a schematic cross-sectional diagram illustrating main portions of a semiconductor light-emitting element 300 according to a reference example.

A semiconductor light-emitting element 3 includes the semiconductor light-emitting portion 15, the first metal layer 51, a metal layer 55, and conductive layers 42a and 42b. The semiconductor light-emitting portion 15 has the first semiconductor layer 10, the semiconductor layer 20 that faces a portion of the first semiconductor layer 10, and the light emitting layer 30 that is provided between a portion of the first semiconductor layer 10 and the semiconductor layer 20.

The semiconductor light-emitting portion 15 has an upper surface 15u that is a surface of the first semiconductor layer 10, and a lower surface 15d that is a surface of the semiconductor layer 20. Furthermore, a portion 10e of the first semiconductor layer 10 is not in contact with the semiconductor layer 20, and is therefore exposed to the metal layer 55.

The semiconductor light-emitting element 3 includes the metal layer 55 that contacts the first semiconductor layer 10 at 10e. The conductive layers 42a and 42b contact the semiconductor layer 20 at the lower surface 15d.

The first surface 14 of the first semiconductor layer 10 includes a first portion 10a and a second portion 10b.

When viewed along the Z-axis direction from the first semiconductor layer 10 to the semiconductor layer 20, the first portion 10a includes a portion that overlaps a contact surface 55c between the first semiconductor layer 10 and the metal layer 55.

When viewed along the Z-axis direction, the second portion 10b includes a portion that overlaps the semiconductor layer 20. The second portion 10b has a rough surface with a pitch, or distance between peaks of the surface, that is longer than the peak wavelength of the emission light that is radiated from the light emitting layer 30. The light emitting layer 30 is provided between the first semiconductor layer 10 and the semiconductor layer 20 at the second portion 10b.

The surface of the first portion 10a is smoother than the surface of the second portion 10b. Any roughness in the surface of the portion 10a has a pitch that is shorter than the peak wavelength of the emission light that is emitted from the light emitting layer 30.

Thus, the first semiconductor layer 10 has an first surface 14 that has a rough portion 10b with a pitch being longer than the peak wavelength of the emission light, and a smoother portion 10a, and a second surface 16 on the side opposite from the first surface 14.

Because the first portion 10a is smoother than the second portion 10b, repetitious reflection of the emitted light between the contact surface 55c and the first surface 14 of the first semiconductor layer 10 may be suppressed.

The semiconductor light-emitting portion 15 has a concave portion 15t that, from the lower surface 15d, reaches the first semiconductor layer 10. The exposure portion 10e of the first semiconductor layer 10 overlaps the concave portion 15t. When viewed along the Z-axis, the first metal layer 51 has a portion that overlaps the semiconductor layer 20.

The metal layer 55 contacts the semiconductor layer 10 in a region of the second surface 16 at a location that is opposite the smoother portion 10a. The metal layer 55 is made of a material that makes good contact with the first semiconductor layer 10. The metal layer 55 may include a stack film of Al, Ni, and Au, in that order from the contact surface 55c.

The conductive layer 42 includes the conductive layer 42a located along the lower surface 15d, and a conductive layer 42b that extends from the conductive layer 42a, outward from the semiconductor light-emitting portion 15. The conductive layer 42a may be a material that reflects the emission light that is radiated from the light emitting layer 30 with high efficiency, for example a stack film that includes a Ag film and a Pt film, which may be deposited in that order starting from the lower surface 15d.

The conductive layer 42b is exposed outward from the semiconductor light-emitting portion 15. The material of the conductive layer 42b may be the same as that of the conductive layer 42a, and the conductive layer 42b and the conductive layer 42a maybe unitary. The pad electrode 44 is formed in an exposed portion of the conductive layer 42b.

FIG. 10B illustrates a semiconductor light-emitting element 300 as a reference example. The first region 51r1 is not present in the semiconductor light-emitting element 300 that is illustrated in FIG. 10B. Therefore, in the semiconductor light-emitting element 300, the light that is radiated from the light emitting layer 30 travels to the first metal layer 51 directly or through the dielectric material layer 85, or a void 51v is formed within the first metal layer 51 during the manufacturing process.

In contrast, in the semiconductor light-emitting element 3 that is illustrated in FIG. 10A, the first region 51r1 is adjacent to the second region 51r2, so light radiated from the light emitting layer 30 cannot reach the first metal layer 51, and no void 51v is formed within the first metal layer 51 during the manufacturing process. Therefore, the light emitting efficiency of the semiconductor light-emitting element 3 is improved, and reliability and manufacturing yield are increased.

### Fourth Embodiment

Any of the semiconductor light-emitting elements 1 to 3 may be mounted in a resin case. FIG. 11 is a schematic cross-sectional diagram of a light-emitting device 100 according to a fourth embodiment. The light emitting device 100 features a resin case 101 in which the semiconductor light-emitting element 1 is disposed, although the semiconductor light-emitting elements 2 and 3 may likewise be disposed in the resin case 101.

In FIG. 11, a reflector 103 is provided on at least a portion of a lateral wall 101w within the resin case 101 and/or on at least a portion of a base portion 101b. The reflector 103 reflects the light that is radiated from the light emitting layer 30a of the semiconductor light-emitting device 1, and is radiated outward from the first metal layer 51 without reaching the first region 51r1 of the first metal layer 51. The light is reflected by the reflector 103 by total reflection or at high reflectance. A material or structure of the reflector 103 is not particularly limited. The material of the reflector 103 may be a metal that has high reflectance. The reflector 103 may have a structure of a dielectric body or a structure of a dielectric body stack that has low absorptivity and low refractivity to achieve total reflection with high efficiency, may have a micro structure with an optical design, or both.

The reflector 103 is inclined at an angle θ, with respect to a line 102 normal to the base portion 101b, that is greater than 0°. Accordingly, light is reflected out of the resin case 101 by the reflector 103, improving light emitting efficiency. Furthermore, any particles that scatter light may be distributed within the resin case 101.

In this disclosure, “nitride semiconductor” is defined as a semiconductor having a composition BₓIn_{y}Al_{z}Ga_{1-x-y-z}N (0≦x≦1, 0≦y ≦1, 0≦z≦1, and x +y+z≦1). The nitride semiconductor may also include other group V elements, other elements to control properties such as conductivity type, or impurities.

In this disclosure, “perpendicular” and “in parallel” are not used only in their respective strict senses, but allow for variation in manufacturing processes. Thus, “parallel” and “perpendicular” include substantially perpendicular and substantially parallel.

In this disclosure, the word “on” in the expression “component A is provided on component B” means that A is positioned over B, that B is positioned over A, that A and B are aligned horizontally, or that A is in contact with BThis usage reflects the fact that configuration of a semiconductor device does not change when the device is rotated.

The embodiments are described above with referring to specific examples. However, the embodiments are not limited to these specific examples. That is, modifications to these specific examples that are made by a person of ordinary skill in the art fall within the scope of the embodiments as long as the modification has characteristics of the embodiments. Structural elements that are included in each of the examples described above, arrangement of the structural elements, materials, conditions, shapes, sizes, and the like are not limited to those that are illustrated, but may be suitably changed.

Furthermore, the structural elements that are described according to each of the embodiments may be combined as long as such a combination is technically possible, and the combination falls within the scope of the embodiments as along as the combination has the characteristics of the embodiments. In addition, with regard to the scope of the gist of the embodiments, a person of ordinary skill in the art may make various improvements and various modification examples and therefore it is understood that such improvements and modification examples fall within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor light-emitting element, comprising:
a stacked body that includes:
a first semiconductor layer that is a first conductivity type,
a second semiconductor layer that is a second conductivity type, and
a light emitting layer between the first semiconductor layer and the second semiconductor layer; and
a first metal layer on the second semiconductor layer, and electrically connected to the second semiconductor layer,
wherein the first metal layer includes a first region that extends outward from the stacked body and a second region that is adjacent to the first region,
wherein a distance between a lower surface of the first metal layer and an upper surface of the first metal layer in the first region is shorter than a distance between the lower surface of the first metal layer and the upper surface of the first metal layer in the second region, and
wherein the lower surface of the first metal layer and the upper surface of the first metal layer in the first region extends along an outer edge of the first metal layer.

2. The semiconductor light-emitting element according to claim 1, further comprising:
a first conductive layer,
wherein the first semiconductor layer has a first surface and a second surface that is opposite to the first surface, the second surface having a first portion and a second portion,
wherein the light emitting layer is selectively disposed on the first portion of the second surface of the first semiconductor layer,
wherein the first conductive layer is electrically connected to the second portion of the second surface of the first semiconductor layer,
wherein the first conductive layer extends outward from the stacked body, and
wherein the first region is provided outward from the first conductive layer.

3. The semiconductor light-emitting element according to claim 2,
wherein a reflectance of the first conductive layer to light that is radiated from the light emitting layer is higher than a reflectance of the first metal layer.

4. The semiconductor light-emitting element according to claim 1, further comprising:
a second metal layer,
wherein the first semiconductor layer has a first surface and a second surface that is opposite to the first surface,
wherein the light emitting layer is selectively provided on the second surface of the first semiconductor layer, and
wherein the second metal layer is electrically connected to the first surface.

5. The semiconductor light-emitting element according to claim 1, further comprising a first conductive layer electrically connected to the first semiconductor layer, wherein the first conductive layer extends outward from the stacked body, and a reflectance of the first conductive layer to light that is radiated from the light emitting layer is higher than a reflectance of the first metal layer.

6. The semiconductor light-emitting element according to claim 5, wherein a surface of the first semiconductor layer facing away from the second semiconductor layer has a plurality of convex portions.

7. The semiconductor light-emitting element according to claim 6, further comprising an electrode on the first conductive layer.

8. The semiconductor light-emitting element according to claim 1, wherein the stacked body is located inward from the second region of the first metal layer.

9. A semiconductor light-emitting element comprising:
a stacked body that includes:
a first semiconductor layer that is a first conductivity type,
a second semiconductor layer that is a second conductivity type,
a light emitting layer disposed between the first semiconductor layer and the second semiconductor layer, and
a first region in which the first semiconductor layer is exposed to the second semiconductor layer; and
a first metal layer disposed on the second semiconductor layer and electrically connected to the first semiconductor layer of the stacked body,
wherein the first metal layer has a first region that extends outward from the stacked body and a second region that is adjacent to the first region,
wherein a distance between a lower end of the first metal layer and an upper end of the first metal layer in the first region is shorter than a distance between the lower end of the first metal layer and the upper end of the first metal layer in the second region, and
wherein a lower surface of the first metal layer and an upper surface of the first metal layer in the first region extends along an outer edge of the first metal layer.

10. The semiconductor light-emitting element according to claim 9, wherein the stacked body is located inward from the second region of the first metal layer.

11. The semiconductor light-emitting element according to claim 9, wherein a surface of the first semiconductor layer facing away from the second semiconductor layer has a plurality of convex portions.

12. The semiconductor light-emitting element according to claim 9, further comprising a first conductive layer electrically connected to the first semiconductor layer, wherein the first conductive layer extends outward from the stacked body, and a reflectance of the first conductive layer to light that is radiated from the light emitting layer is higher than a reflectance of the first metal layer.

13. The semiconductor light-emitting element according to claim 9, further comprising an electrode on the first metal layer and connected to the second semiconductor layer.

14. A light emitting device, comprising:
the semiconductor light-emitting element according to claim 1; and
a reflector that reflects light radiated from the light emitting layer of the semiconductor light-emitting element outward from the stacked body thereof without reaching the first region of the first metal layer.

15. The light emitting device according to claim 14, wherein the semiconductor light-emitting element further comprises a first conductive layer electrically connected to the first semiconductor layer, wherein the first conductive layer extends outward from the stacked body, and a reflectance of the first conductive layer to light that is radiated from the light emitting layer is higher than a reflectance of the first metal layer.

16. The light emitting device according to claim 14, wherein a surface of the first semiconductor layer facing away from the second semiconductor layer has a plurality of convex portions.

17. The light emitting device according to claim 16, wherein the semiconductor light-emitting element further comprises an electrode on the first conductive layer.

18. A method of manufacturing a semiconductor light-emitting element, comprising:
forming a stacked body with a light emitting region and a mesa region, the light emitting region including:
a first semiconductor layer that has a first surface and a second surface opposite the first surface, and that is a first conductivity type;
a first light emitting layer selectively disposed on the second surface of the first semiconductor layer; and
a second semiconductor layer that, along with the first semiconductor layer, sandwiches the first light emitting layer, the second semiconductor layer having a second conductivity type, wherein the mesa region includes: the first semiconductor layer;
a second light emitting layer that is selectively disposed on the second surface of the first semiconductor layer; and
a third semiconductor layer that, along with the first semiconductor layer, sandwiches the second light emitting layer, the third semiconductor layer having the second conductivity type;
forming a first insulating layer that covers the second surface of the first semiconductor layer, the light emitting region, and the mesa region;
forming a first conductive layer that is electrically connected to the second surface of the first semiconductor layer, and that covers a portion of the first insulation layer;
forming a second insulating layer that covers the first insulating layer and the first conductive layer;
etching the second insulating layer and the first insulating layer to expose the second semiconductor layer;
forming a first metal region that is electrically connected to the second semiconductor layer, covers the second insulating layer, and includes a first region to which a pattern of the mesa region is transferred;
forming a first metal layer that connects a second metal region and the first metal region; and
removing the mesa region and a portion of the first semiconductor layer in such a manner that the first metal layer extends outward from the stacked body.

19. The method according to claim 18, further comprising:
cutting the first region of the first metal layer in a direction from the first semiconductor layer to the second semiconductor layer.

20. The method according to claim 19, further comprising forming a reflective metal layer on the exposed portions of the second semiconductor layer.
